(19) United States
(12) Patent Application Publication
(10) Pub. No.: US 2026/0269812 A1
(43) Pub. Date: Sep. 10, 2026

(54) CLOCK GENERATING MECHANISM CAPABLE OF MITIGATING CLOCK GLITCHES OF DIGITAL CIRCUIT BY SELECTING GOOD/BETTER TIMING TO OUTPUT RECEIVED FREQUENCY CONTROL SIGNAL

(71) Applicant: PixArt Imaging Inc., Hsin-Chu City (TW)

(72) Inventors: Jheng-Liang Chen, Hsin-Chu City (TW); Chia-Pei Chen, Hsin-Chu City (TW); Tung-Ying Chiang, Hsin-Chu City (TW)

(73) Assignee: PixArt Imaging Inc., Hsin-Chu City (TW)

(21) Appl. No.: 19/070,500

(22) Filed: Mar. 4, 2025

(51) Int. Cl. H03K 5/01; H03K 5/00

(52) U.S. Cl. CPC H03K 3/0231; H03K 3/354; H03K 4/501

(57) ABSTRACT

A method of a clock generating device includes: providing an oscillator circuit to use a specific capacitor to generate an oscillation frequency signal; receiving a control signal and delaying the control signal with a specific delay amount when the specific capacitor is in a charging state, the control signal being used to determine a frequency of the oscillation frequency signal generated by the oscillator circuit and being sent from a frequency control circuit; and, outputting the delayed control signal into the oscillator circuit in response to an event that the specific capacitor exits the charging state and enters a corresponding reset state.

### BACKGROUND OF THE INVENTION

### 1. FIELD OF THE INVENTION

The invention relates to a clock generating mechanism, and more particularly to a clock generating device and a corresponding method.

### 2. DESCRIPTION OF THE PRIOR ART

Generally speaking, in a conventional digital system, clock signals may not be free from glitches during operation, and abnormal behavior may occur. This is because clock glitches (unwanted, brief pulses or transitions) can cause timing violations and incorrect operation of sequential circuits.

### SUMMARY OF THE INVENTION

Therefore one of the objectives of the invention is to provide a clock generating device and a corresponding method, to solve the problems.

According to the embodiments of the invention, a clock generating device is disclosed. The clock generating device comprises an oscillator circuit and a control circuit. The oscillator circuit is used for using a specific capacitor to generate an oscillation frequency signal. The control circuit, coupled to the oscillator circuit, is used for receiving a control signal and delaying the control signal with a specific delay amount when the specific capacitor is in a charging state. The control signal is used to determine a frequency of the oscillation frequency signal generated by the oscillator circuit and is sent from a frequency control circuit. The control circuit is used to output the delayed control signal into the oscillator circuit in response to an event that the specific capacitor exits the charging state and enters a corresponding reset state.

According to the embodiments, a method of a clock generating device is further disclosed. The method comprises: providing an oscillator circuit to use a specific capacitor to generate an oscillation frequency signal; receiving a control signal and delaying the control signal with a specific delay amount when the specific capacitor is in a charging state, the control signal being used to determine a frequency of the oscillation frequency signal generated by the oscillator circuit and being sent from a frequency control circuit; and, outputting the delayed control signal into the oscillator circuit in response to an event that the specific capacitor exits the charging state and enters a corresponding reset state.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a clock generating device according to an embodiment of the invention.

FIG. 2 is a diagram of an example of the operations of clock generating device according to an embodiment of the invention.

FIG. 3 is a diagram of another example of the operations of clock generating device according to a different embodiment of the invention.

FIG. 4 is a diagram of another example of the operations of clock generating device according to a different embodiment of the invention.

FIG. 5 is a flowchart diagram of operations of the clock generating device 100 as shown in FIG. 1 according to an embodiment of the invention.

### DETAILED DESCRIPTION

The invention aims at providing a technical solution of clock generating device and corresponding method capable of mitigating/avoiding clock glitches (or jitters)of a digital circuit by selecting a good/better timing to output a received control signal sent from a frequency control circuit to control an oscillator circuit at the selected timing. Specifically, the received control signal may be outputted to control the oscillator circuit when/after the oscillator circuit exits a charging state and enters a reset state.

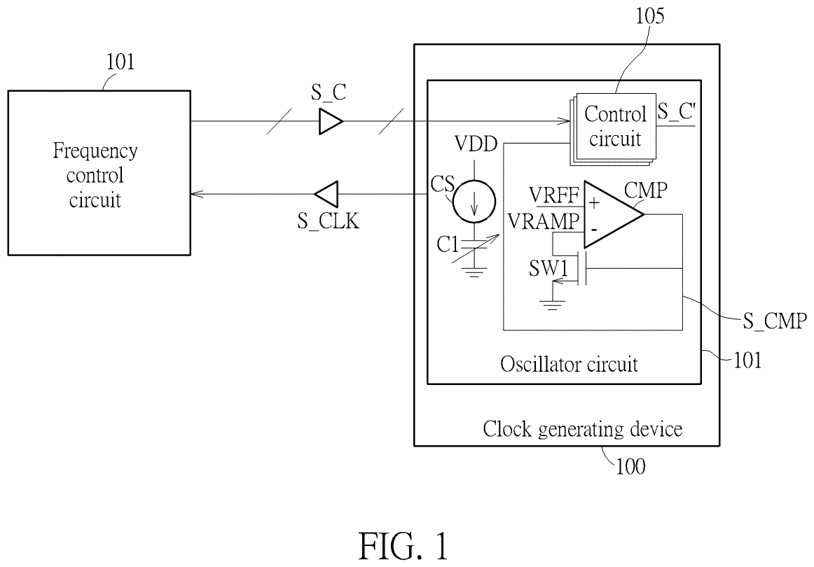

FIG. 1 is a diagram of a clock generating device 100 according to an embodiment of the invention. The clock generating device 100 comprises an oscillator circuit 110 and a control circuit 105, and it is externally coupled to a frequency control circuit 101.

The oscillator circuit 110 is used for using a specific capacitor C1 to generate an oscillation frequency signal. The control circuit 105, coupled to the oscillator circuit 110, is used for receiving a control signal S_C, which is used to control/determine a frequency of the oscillation frequency signal generated by the oscillator circuit 110, sent from a frequency control circuit 101. In practice, in the embodiments of the invention, the oscillator circuit 110 comprises a current source CS, the specific capacitor C1 such as an adjustable capacitor, a comparator CMP, and a switch transistor SW1.

The current source CS, coupled between a supply voltage level VDD and a first node of the specific capacitor C1, is controlled by a first frequency code of the control signal S_C sent from the frequency control circuit 101 to generate and provide a variable charging current for the first node of the specific capacitor C1. The specific capacitor C1, e.g. an adjustable capacitor, is coupled between the current source CS and the ground level and is controlled by a second frequency code of the control signal S_C to provide a variable capacitance. The specific capacitor C1 having the variable capacitance is used to be charged by the variable charging current to generate a charging voltage VRAMP (which is a variable voltage level) at the first node of the specific capacitor C1. The value of variable charging current and value of variable capacitance are respectively determined based on the first frequency code and second frequency code of control signal S_C. The charging voltage VRAMP will be gradually increased due to the electrical charge accumulated and stored by the specific capacitor C1 if the switch transistor SW1 is not conductive, and the charging voltage VRAMP will be rapidly decreased if the switch transistor SW1 is conductive.

The comparator CMP has a first input node (i.e. positive input) coupled to a reference voltage VREF, a second input node (i.e. negative input) coupled to the charging voltage VRAMP, and has an output node. The comparator CMP is used for comparing the reference voltage VREF with the charging voltage VRAMP to generate a comparison result signal S_CMP at its output node to generate the oscillation frequency signal S_CLK corresponding to the comparison result signal S_CMP. When the charging voltage VRAMP is lower than the reference voltage VREF, the comparator CMP outputs the logic high level ‘1’ as the comparison result signal S_CMP at its output node. When the charging voltage VRAMP becomes higher than the reference voltage VREF, the comparator CMP outputs the logic low level ‘0’ as the comparison result signal S_CMP at its output node. Then, the oscillator circuit 110 generates and outputs the frequency of the oscillation frequency signal S_CLK based on the frequency of comparison result signal S_CMP. For example (but not limited), the oscillator circuit 110 performs a frequency dividing operation upon the comparison result signal S_CMP with a factor 2 to generate the oscillation frequency signal S_CLK. By doing so, the first and second frequency codes of control signal S_C can be used to respectively control the variable charging current and variable capacitance so as to control the frequency value of the generated oscillation frequency signal S_CLK.

The switch transistor SW1 has a first node coupled to the first input node of the specific capacitor C1, a second node coupled to the ground level, and has a control node coupled to the comparison result signal S_CMP. For example, the switch transistor SW1 is a PMOS transistor which is turned on by the logic low level ‘0’ of comparison result signal S_CMP and is turned off by the logic high level ‘1’ of comparison result signal S_CMP. The charging voltage VRAMP is gradually increased when the switch transistor SW1 is at the turned-off state. Once the charging voltage VRAMP becomes higher than the reference voltage VREF, the previously turned-off switch transistor SW1 is immediately turned on by the logic low level ‘0’ to discharge the specific capacitor C1 (i.e. dissipation of stored electrical charge from the specific capacitor C1 through the turned-on switch transistor SW1). In this situation, the charging voltage VRAMP is rapidly decreased down to zero when the switch transistor SW1 is at the turned-on state.

That is, the specific capacitor C1 having the variable capacitance is to be charged by the variable charging current, provided by the current source CS in response to the first frequency code of the control signal S_C during a charging time interval of a charging state in which the switch transistor SW1 is at the turned-off state, and then the specific capacitor C1 is to be discharged through the switch transistor SW1 during a discharging time interval of a discharging/reset state (or called as a reset time interval) in which the switch transistor SW1 is at the turned-on state. Then, once the switch transistor SW1 exits the turned-on state and enters the turned-off state again, the specific capacitor C1 is to be charged by the variable charging current during the next charging time interval which follows the above-mentioned reset time interval which follows the previous charging time interval.

In the embodiments, for mitigating/avoiding clock jitters of a digital circuit by selecting a good/better timing to output the received control signal S_C sent from the frequency control circuit 101, the control circuit 105 can be used to dynamically delay the received control signal S_C with a specific delay amount, and the specific delay amount may be a variable delay amount. The control circuit 105 can detect the comparison result signal S_CMP outputted from the oscillator circuit 110 to dynamically determine the specific delay amount. That is, the control circuit 105 may have a detection circuit (not shown in FIG. 1) for detecting the generated comparison result signal S_CMP and also have a buffer circuit (not shown in FIG. 1) for delaying and buffering the received control signal S_C.

In practice, the control circuit 105 can detect the signal edge (i.e. level switching) and/or different logic levels of the comparison result signal S_CMP generated by the oscillator circuit 110 to determine the specific delay amount. For example, for the delay operation, the control circuit 105 initially may directly use the currently received control signal S_C to control the oscillator circuit 110 without delaying the currently received control signal S_C, then may refer to the generated comparison result signal S_CMP to determine the specific delay amount, and then may delay a subsequently received control signal S_C with the determined specific delay amount to output a delayed control signal to control the oscillator circuit 110 generating the oscillation frequency signal again. Equivalently, the control circuit105 is used to delay and buffer the control signal S_C, and the control circuit105 is used to output the delayed control signal to the oscillator circuit 110 after the specific capacitor exits the charging state.

Further, in one embodiment, the control circuit 105 can detect whether the control signal S_C is changed or not to determine whether to delay the control signal S_C. For example, the specific delay amount can be set as zero by the control circuit 105 if the control circuit 105 detects that the control signal S_C is not changed at this timing compared to the previous timing. If the control circuit 105 detects that the control signal S_C is changed at this timing compared to the previous timing, the control circuit 105 can delay the control signal S_C currently received at this timing to avoid the clock glitches of a digital circuit such as the comparator CMP. Thus, the control circuit 105 can determine whether to delay the control signal S_C in response to different situations.

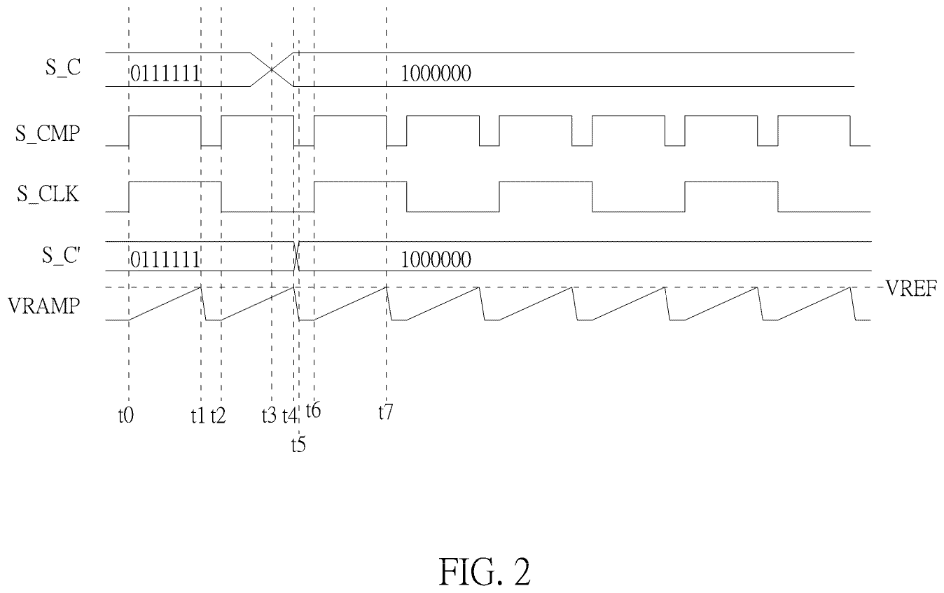

In one embodiment, the delay timing selected by the control circuit 105 to output the control signal S_C is directly associated with a timing of a falling edge occurring in the comparison result signal S_CMP. FIG. 2 is a diagram of an example of the operations of clock generating device 100 according to an embodiment of the invention. As shown in FIG. 2, the control signal S_C indicates that a first control signal having a frequency code such as ‘0111111’ is received by the control circuit 105 before time t3 and a second control signal having a frequency code such as ‘1000000’ is received by the control circuit 105 after time t3; that is, the control signal S_C initially is the first control signal and changes from the first control signal into the second control signal at time t3. The first and second control signals are used to control different frequency values of oscillation frequency signal S_CLK. The signal S_C′ indicates a control signal outputted from the control circuit 105 by dynamically delaying the control signal S_C. in this example, when receiving the second control signal having a frequency code such as ‘1000000’ at time t3, the control circuit 105 is arranged to delay the second control signal with a specific delay amount from t3 to t4 (or equivalently from t3 to t5).

Initially at Time T0, the Control Signal S_C Is the First control, signal having frequency code such as ‘0111111’ (but not limited) and is directly outputted from the control circuit 105 into the oscillator circuit 110 without being delayed, and a rising edge occurs in the comparison result signal S_CMP. In this situation, during a charging time period from t0 to t1, the oscillator circuit 110 is in the charging mode, and the charging voltage VRAMP is gradually increased due to that the comparison result signal S_CMP currently is at the logic high level. At time t1, a falling edge occurs in the comparison result signal S_CMP when the charging voltage VRAMP becomes higher than the reference voltage VREF, and then the charging voltage VRAMP is rapidly decreased down to zero due to that the comparison result signal S_CMP currently is at the logic low level. During the reset time period from t1 to t2, the oscillator circuit 110 is in the reset mode. Similarly, at time t2, a rising edge occurs again in the comparison result signal S_CMP, and during a charging time period from t2 to t4, the oscillator circuit 110 is in the charging mode, and the charging voltage VRAMP is gradually increased due to that the comparison result signal S_CMP currently is at the logic high level. It should be noted that, before time t3 at which the control signal S_C changes from the first control signal having frequency code ‘0111111’into the second control signal having frequency code ‘1000000’, the control circuit 105 is used to directly output the received first control signal having frequency code ‘0111111’ without delaying the received first control signal; that is, in this situation the specific delay amount is zero.

When the control circuit 105 in the charging mode detects that the control signal S_C changes from the first control signal having frequency code ‘0111111’ into the second control signal having frequency code ‘1000000’ at time t3, the control circuit 105 is arranged to delay the currently received control signal S_C (i.e. second control signal having frequency code ‘1000000’) with the specific delay amount such as a time period from t3 to t4. That is, in this situation, the control circuit 105 outputs the second control signal having frequency code ‘1000000’ after time t4, and the oscillator circuit 110 is still controlled by the same first control signal having frequency code ‘0111111’ during the time period from t3 to t4. In practice, the control circuit 105 is used to output the delayed second control signal having frequency code ‘1000000’ to the oscillator circuit 110 in response to a falling edge occurring in the comparison result signal S_CMP.

Then, at time t4, a falling edge occurs in the comparison result signal S_CMP when the charging voltage VRAMP becomes higher than the reference voltage VREF, and then the charging voltage VRAMP is rapidly decreased down to zero due to that the comparison result signal S_CMP currently is at the logic low level. During the reset time period from t4 to t6, the oscillator circuit 110 is in the reset mode. Similarly, at time t6, a rising edge occurs again in the comparison result signal S_CMP, and during a charging time period from t6 to t7, the oscillator circuit 110 is in the charging mode, and the charging voltage VRAMP is gradually increased due to that the comparison result signal S_CMP currently is at the logic high level. It should be noted that, after time t4 at which the rising edge occurs in the comparison result signal S_CMP, the control circuit 105 is used to directly output the currently received control signal S_C (i.e. the second control signal having frequency code ‘1000000’) without delaying the second control signal; that is, after time t4, the specific delay amount is set as zero. In addition, in this embodiment, the oscillator circuit 110 performs a frequency dividing operation upon the comparison result signal S_CMP with a factor value 2 to generate the oscillation frequency signal S_CLK. However, this is not intended to be a limitation of the invention.

In another embodiment, the specific delay amount can be set as a different delay amount. Similarly, as shown in FIG. 2, when the control circuit 105 in the charging mode detects that the control signal S_C changes from the first control signal having frequency code ‘0111111’ into the second control signal having frequency code ‘1000000’ at time t3, the control circuit 105 may delay the currently received control signal S_C (i.e. second control signal having frequency code ‘1000000’) with the specific delay amount such as a time period from t3 to t5. That is, in this situation, the control circuit 105 outputs the second control signal having frequency code ‘1000000’ after time t5 which is a time point that the charging voltage VRAMP decreases down to zero, and the oscillator circuit 110 is still controlled by the same first control signal having frequency code ‘0111111’ during the time period from t3 to t5.

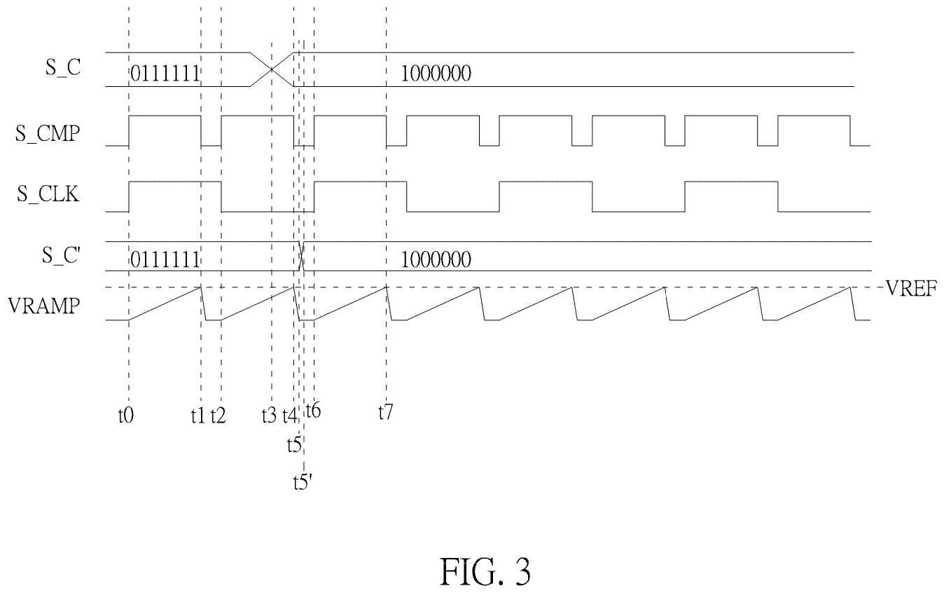

FIG. 3 is a diagram of another example of the operations of clock generating device 100 according to a different embodiment of the invention. For example, as shown in FIG. 3, when the control circuit 105 in the charging mode detects that the control signal S_C changes from the first control signal having frequency code ‘0111111’ into the second control signal having frequency code ‘1000000’ at time t3, the control circuit 105 may delay the currently received control signal S_C (i.e. second control signal having frequency code ‘1000000’) with the specific delay amount such as a time period from t3 to a selected time point, and the selected time point can be any time point between time t4 and time t6. That is, the control circuit 105 may output the second control signal having frequency code ‘1000000’ at any time point when the control circuit 105 is in the reset mode. For example (but not limited), the selected time point may be time t5′. The oscillator circuit 110 is still controlled by the same first control signal having frequency code ‘0111111’ during the time period from t3 to the selected time point such as time t5′.

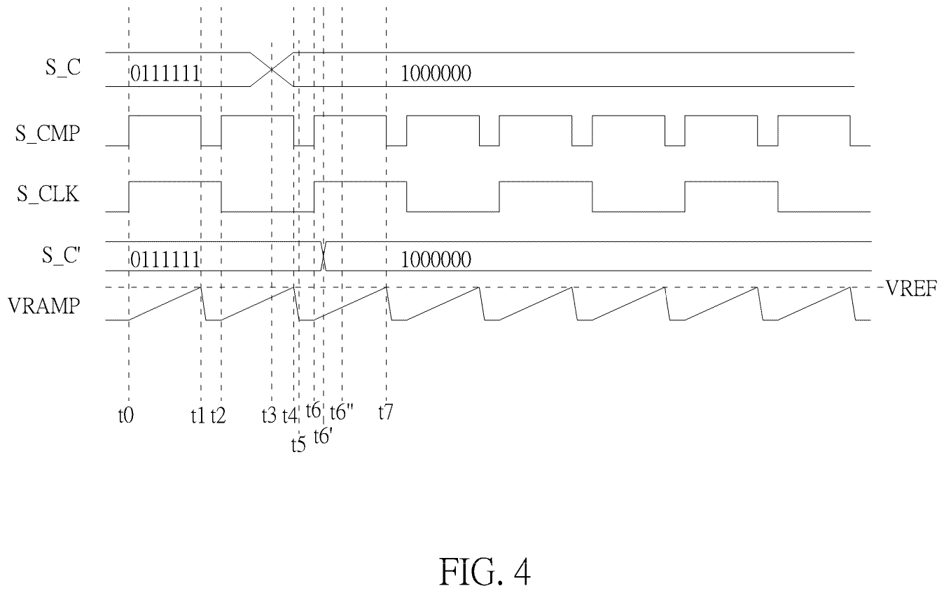

FIG. 4 is a diagram of another example of the operations of clock generating device 100 according to a different embodiment of the invention. In other embodiments, the specific capacitor C1 may comprise a charging state/mode which is formed by an initial charging state and a normal charging state which follows the initial charging state. For example (but not limited), the initial charging state may correspond to a beginning percentage portion of the charging time period, and the normal charging state may correspond to a remaining percentage portion of the charging time period. That is, the selected time point for outputting a delayed control signal may be any time point when the specific capacitor C1 is at the reset state or the initial charging state. For example (but not limited), as shown in FIG. 4, when the control circuit 105 in the charging mode detects that the control signal S_C changes from the first control signal having frequency code ‘0111111’ into the second control signal having frequency code ‘1000000’ at time t3, the control circuit 105 may delay the currently received control signal S_C (i.e. second control signal having frequency code ‘1000000’) with the specific delay amount such as a time period from t3 to a selected time point, and the selected time point can be any time point corresponding to the initial charging state which is associated with an initial charging time period between time t6 and time t6″ (e.g. a beginning percentage portion (e.g. 30%, but not limited) of a next logic high level (from t6 to t7) next to a logic low level (from t5 to t6)). That is, the control circuit 105 may output the second control signal having frequency code ‘1000000’ at any time point when the control circuit 105 is in the reset mode. For example (but not limited), the selected time point may be time t6′. The oscillator circuit 110 is still controlled by the same first control signal having frequency code ‘0111111’ during the time period from t3 to the selected time point such as time t6′.

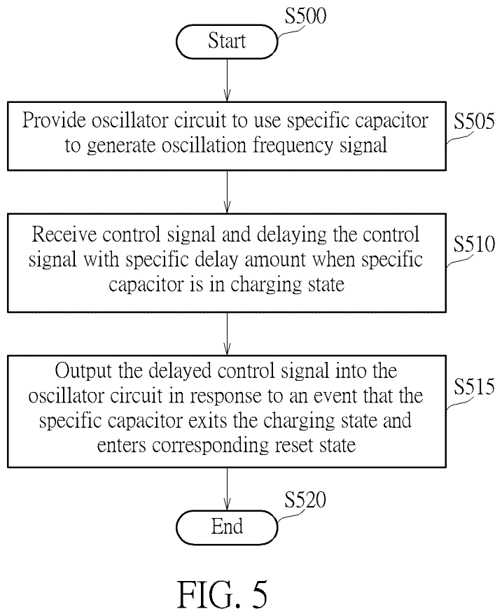

To make readers more clearly understand the invention, FIG. 5 is provided. FIG. 5 is a flowchart diagram of operations of the clock generating device 100 as shown in FIG. 1 according to an embodiment of the invention. The descriptions of the steps are described in the following:

Step S500: Start;

Step S505: Provide an oscillator circuit to use a specific capacitor to generate an oscillation frequency signal;

Step S510: Receive a control signal and delaying the control signal with a specific delay amount when the specific capacitor is in a charging state; the control signal is used to determine a frequency of the oscillation frequency signal generated by the oscillator circuit and is sent from a frequency control circuit;

Step S515: Output the delayed control signal into the oscillator circuit in response to an event that the specific capacitor exits the charging state and enters a corresponding reset state; and

Step S520: End.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A clock generating device, comprising:
an oscillator circuit, for using a specific capacitor to generate an oscillation frequency signal; and
a control circuit, coupled to the oscillator circuit, for receiving a control signal and delaying the control signal with a specific delay amount when the specific capacitor is in a charging state, the control signal being used to determine a frequency of the oscillation frequency signal generated by the oscillator circuit and being sent from a frequency control circuit;
wherein the control circuit is used to output the delayed control signal into the oscillator circuit in response to an event that the specific capacitor exits the charging state and enters a corresponding reset state.

2. The clock generating device of claim 1, wherein the control circuit is used to delay the control signal and then output the delayed control signal into the oscillator circuit at a specific time within a rest time period corresponding to the corresponding reset state.

3. The clock generating device of claim 1, wherein the control circuit is used to delay the control signal and then output the delayed control signal into the oscillator circuit immediately when the specific capacitor exits the charging state and enters the corresponding reset state.

4. The clock generating device of claim 1, wherein the specific capacitor comprises a next charging state following the corresponding reset state, and the next charging state comprises an initial charging state and a normal charging state which follows the initial charging state; the control circuit is used to delay the control signal and then output the delayed control signal into the oscillator circuit at a specific time within a time period corresponding to the initial charging state of the next charging state.

5. The clock generating device of claim 1, wherein the oscillator circuit comprises:
a specific current source, coupled to a supply voltage level and the specific capacitor, being controlled by a first frequency code of the control signal sent from the frequency control circuit to generate a variable charging current for a first node of the specific capacitor;
the specific capacitor, coupled between the specific current source and a ground level, being controlled by a second frequency code of the control signal to provide a variable capacitance and being charged by the variable charging current to generate a charging voltage at the first node;
a comparator, having a first input node coupled to a reference voltage, having a second input node coupled to the charging voltage, and having an output node, for comparing the reference voltage with the charging voltage to generate a comparison result signal at the output node; and
a switch transistor, having a first node coupled to the first input node of the specific capacitor, a second node coupled to the ground level, and a control node coupled to the comparison result signal;
wherein the oscillator circuit is arranged to determine the frequency of the oscillation frequency signal based on a frequency of the comparison result signal.

6. The clock generating device of claim 5, wherein the control circuit is used to delay the control signal and then output the delayed control signal into the oscillator circuit in response to an event that a falling edge occurs in the comparison result signal; when the falling edge occurs in the comparison result signal due to that the charging voltage becomes higher than the reference voltage, the switch transistor is turned on by the falling edge to make the specific capacitor enter a reset state to reset the charging voltage.

7. The clock generating device of claim 6, wherein the control circuit is used to delay the control signal and then output the delayed control signal into the oscillator circuit when the comparison result signal is at a logic low level.

8. The clock generating device of claim 6, wherein the control circuit is used to delay the control signal and then output the delayed control signal into the oscillator circuit when the comparison result signal is at a beginning percentage portion of a next logic high level next to a logic low level.

9. The clock generating device of claim 1, wherein when the control circuit detects that the control signal changes from a first control signal into a second control signal, the control circuit is used to delay the control signal and then output the delayed control signal into the oscillator circuit in response to the event that the specific capacitor exits the charging state and enters the corresponding reset state.

10. A method of a clock generating device, comprising:
providing an oscillator circuit to use a specific capacitor to generate an oscillation frequency signal;
receiving a control signal and delaying the control signal with a specific delay amount when the specific capacitor is in a charging state, the control signal being used to determine a frequency of the oscillation frequency signal generated by the oscillator circuit and being sent from a frequency control circuit; and
outputting the delayed control signal into the oscillator circuit in response to an event that the specific capacitor exits the charging state and enters a corresponding reset state.

11. The method of claim 10, further comprising:
delaying the control signal and then outputting the delayed control signal into the oscillator circuit at a specific time within a rest time period corresponding to the corresponding reset state.

12. The method of claim 10, further comprising:
delaying the control signal and then outputting the delayed control signal into the oscillator circuit immediately when the specific capacitor exits the charging state and enters the corresponding reset state.

13. The method of claim 10, wherein the specific capacitor comprises a next charging state following the corresponding reset state, and the next charging state comprises an initial charging state and a normal charging state which follows the initial charging state; and, the method further comprises:
delaying the control signal and then outputting the delayed control signal into the oscillator circuit at a specific time within a time period corresponding to the initial charging state of the next charging state.

14. The method of claim 10, further comprising:
providing a specific current source, coupled to a supply voltage level and the specific capacitor, being controlled by a first frequency code of the control signal sent from the frequency control circuit to generate a variable charging current for a first node of the specific capacitor;
providing the specific capacitor, coupled between the specific current source and a ground level, being controlled by a second frequency code of the control signal to provide a variable capacitance and being charged by the variable charging current to generate a charging voltage at the first node;
providing a comparator, having a first input node coupled to a reference voltage, having a second input node coupled to the charging voltage, and having an output node, to compare the reference voltage with the charging voltage to generate a comparison result signal at the output node;
providing a switch transistor, having a first node coupled to the first input node of the specific capacitor, a second node coupled to the ground level, and a control node coupled to the comparison result signal; and
determining the frequency of the oscillation frequency signal based on a frequency of the comparison result signal.

15. The method of claim 14, further comprising:
delaying the control signal and then outputting the delayed control signal into the oscillator circuit in response to an event that a falling edge occurs in the comparison result signal; and
when the falling edge occurs in the comparison result signal due to that the charging voltage becomes higher than the reference voltage, turning on the switch transistor by the falling edge to make the specific capacitor enter a reset state to reset the charging voltage.

16. The method of claim 15, further comprising:
delaying the control signal and then outputting the delayed control signal into the oscillator circuit when the comparison result signal is at a logic low level.

17. The method of claim 15, further comprising:
delaying the control signal and then outputting the delayed control signal into the oscillator circuit when the comparison result signal is at a beginning percentage portion of a next logic high level next to a logic low level.

18. The method of claim 10, further comprising:
when detecting that the control signal changes from a first control signal into a second control signal, delaying the control signal and then outputting the delayed control signal into the oscillator circuit in response to the event that the specific capacitor exits the charging state and enters the corresponding reset state.
